(19) United States
(12) Patent Application Publication
(10) Pub. No.: US 2023/0187284 A1
(43) Pub. Date: Jun. 15, 2023

(54) IN-SITU FEEDBACK FOR LOCALIZED COMPENSATION

(71) Applicant: International Business Machines Corporation, Armonk, NY (US)

(72) Inventors: Saumya Sharma, Easton, CT (US); Ruturaj Nandkumar Pujari, Albany, NY (US); Ashim Dutta, Clifton Park, NY (US); Chih-Chao Yang, Glenmont, NY (US)

(21) Appl. No.: 17/551,266

(22) Filed: Dec. 15, 2021

(51) Int. Cl. H01L 21/66; H01L 21/67

(52) U.S. Cl. CPC H01L 22/12; H01L 21/67253; H01L 22/26; H01L 22/34

(57) ABSTRACT

Embodiments of the present invention are directed to in-situ wafer feedback schemes and systems for providing localized process-based compensation on a semiconductor wafer. In a non-limiting embodiment of the invention, a plurality of test structures are formed on a surface of a semiconductor wafer. The semiconductor wafer is placed under a detection surface of an in-situ feedback tool comprising one or more sensors. The in-situ feedback tool measures a property of each of the plurality of test structures and determines a local condition of the semiconductor wafer for each measured property of the plurality of test structures. A localized process-based compensation is provided on the surface of the semiconductor wafer for each local condition.

### BACKGROUND

The present invention generally relates to fabrication methods and resulting structures for integrated circuits (ICs), and more specifically, to processing methods and fabrication tools configured to provide in-situ wafer feedback for localized process-based compensation.

IC fabrication involves a series of complex manufacturing and diagnostic steps, typically performed on silicon wafers. A complete fabrication cycle generally starts from a bare wafer (bare silicon) which undergoes various patterning and other fabrication processes to build up the various transistors, interconnects, and other discrete components that make up the completed IC. Typically, a large number of microchips are built on a single IC wafer and are split (diced) from the wafer to define individual chips. A wafer typically begins processing by transferring a schematic diagram (or physical layout) of a desired circuit onto a surface of the wafer. The schematic diagram is “printed” on the wafer surface with a very small geometric ratio. The schematic diagram is composed of various elements which make up the IC, such as transistors, conductive interconnects (lines, vias, etc.) that transmit signals throughout the IC, and spaces between the interconnects.

### SUMMARY

Embodiments of the invention are directed to a method of using a processor to control an in-situ feedback tool to perform process-based compensation. A non-limiting example of the method includes using the processor to direct one or more sensors of the in-situ feedback tool to measure a property of each of a plurality of test structures on a surface of a semiconductor wafer. The processor determines a local condition of the semiconductor wafer for each measured property of the plurality of test structures and a localized process-based compensation for each local condition. The processor directs a lithography module to provide, for each local condition, the respective localized process-based compensation on the surface of the semiconductor wafer.

Embodiments of the invention are directed to a method for forming a semiconductor device using in-situ wafer feedback. A non-limiting example of the method includes forming a first test structure and a second test structure on a surface of a semiconductor wafer. An in-situ feedback tool measures a first height of the first test structure and a second height of the second test structure. A difference between the first height and the second height is compared to a predetermined threshold. In response to the difference in heights satisfying the predetermined threshold, a localized process-based compensation is provided on the surface of the semiconductor wafer.

Embodiments of the invention are directed to a semiconductor fabrication system for in-situ process-based compensation. A non-limiting example of the semiconductor fabrication system includes an in-situ feedback tool having one or more sensors, a lithography module, and a processor. The processor is configured to direct the one or more sensors of the in-situ feedback tool to measure a property of each of a plurality of test structures on a surface of a semiconductor wafer. The processor is further configured to determine a local condition of the semiconductor wafer for each measured property of the plurality of test structures and to determine a localized process-based compensation for each local condition. The processor is further configured to direct the lithography module to provide, for each local condition, the respective localized process-based compensation on the surface of the semiconductor wafer.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a cross-sectional view and a top-down view of a semiconductor structure configured with one or more test structures according to one or more embodiments of the invention;

FIG. 1B depicts an example compensation mapping according to one or more embodiments of the invention;

FIG. 2A depicts a cross-sectional view of a semiconductor structure configured with one or more test structures according to one or more embodiments of the invention;

FIG. 2B depicts an example topography compensation according to one or more embodiments of the invention;

FIG. 3A depicts a cross-sectional view of a semiconductor structure configured with one or more test structures according to one or more embodiments of the invention;

FIG. 3B depicts an example wafer bow measurement according to one or more embodiments of the invention;

FIG. 3C depicts an example wafer bow compensation according to one or more embodiments of the invention;

FIG. 4 depicts a flow diagram illustrating a method according to one or more embodiments of the invention;

FIG. 5 depicts a flow diagram illustrating a method according to one or more embodiments of the invention; and

FIG. 6 depicts a computing system capable of implementing aspects of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

The transistors, interconnects, and other discrete components that make up a microchip circuit are manufactured at increasingly smaller geometries to satisfy continuously scaling power and efficiency requirements. As microchip fabrication continues to call for increasingly smaller geometries, for example, line widths below 10 nm, the effects of process drift and process variation on the actual printing (lithography) process have been greatly amplified. For example, due to difficulties in manufacturing increasingly small device geometries, the actual printed pattern in the wafer (the achieved structure) may differ somewhat from the desired pattern (the schematic diagram).

The continued scaling of semiconductor components has resulted in challenging fabrication requirements during each of these stages. Advanced patterning processes incorporate phase-shifting, optical proximity correction, and other practices to satisfy these scaling demands, and can achieve, for example, critical dimensions (CD) and a line-to-line pitch below 20 nm. In an ideal scenario, the actual printed pattern on the wafer should look exactly the same as the design pattern. In reality, however, even small process variations result in some differences between the desired pattern and the physically printed pattern. These differences may be both subtle and significant, and they can be both random and systematic. The degree of error or difference between the target pattern and the physically printed pattern can degrade the electrical performance of the circuit, can result in a loss of actual yield, and can cause delays in the production of semiconductor devices.

As semiconductors continue to scale to smaller nodes, small wafer variations which could be ignored at higher technology nodes now result in problematic drift between printed patterns (the achieved structures) and desired patterns (from the schematic diagram or layout design) on the wafer. Observe, for example, the impact of a 2 nm patterning drift in an interconnect having a line-to-line pitch of 100 nm (roughly 2 percent drift) versus a line-to-line pitch of 10 nm (roughly 20 percent drift).

Turning now to an overview of aspects of the present invention, one or more embodiments of the invention address the above-described shortcomings by leveraging an in-situ wafer feedback scheme for localized process-based compensation. To ensure high quality semiconductor manufacturing, aspects of the present invention account for any wafer/chip level variations by compensating for such variations in-situ, that is, while processing at each fabrication step.

In some embodiments of the invention, one or more test structures are placed or patterned across the wafer surface to provide a target for an in-situ feedback tool. The test structures can be distributed as desired to increase or decrease in-situ feedback resolution (for example, 1 test structure per die/wafer section, 9 test structures per die, 100 test structures per die, etc.). The in-situ feedback tool is configured to measure a compensation property at each region of the wafer having a test structure. In some embodiments of the invention, the compensation property is a height of the test structure relative to a reference point. Other compensation properties are possible, such as a shape, size, and reflectivity of the test structure. Once known, the compensation property can be leveraged to tweak or otherwise adjust manufacturing conditions for the respective region of the wafer. For example, focus depth can be varied during lithography depending on local topography. In this manner, localized in-situ compensation can be provided throughout the wafer to reduce or eliminate drift between physically printed patterns and their respective layout designs.

Providing in-situ wafer feedback and localized process-based compensation according to one or more embodiments offers several technical benefits over conventional fabrication processes. For example, these techniques can be used to provide highly localized process adjustments to account for topography variations across the wafer. In another example, these techniques can be used to compensate for wafers having arbitrary degrees of wafer bow.

Advantageously, localized process-based compensation schemes according to one or more embodiments can be varied at each step of integration flow and can even vary for different parts of the wafer (e.g., topography variations in edge and center regions of the wafer can be handled differently). Moreover, some portion of the compensation can be moved on tool to account for variations introduced off-wafer. Consider, for example, that when clamping down a bowed wafer during processing the signature of wafer warpage or height compensation might be different than when the bowed wafer is observed prior to clamping.

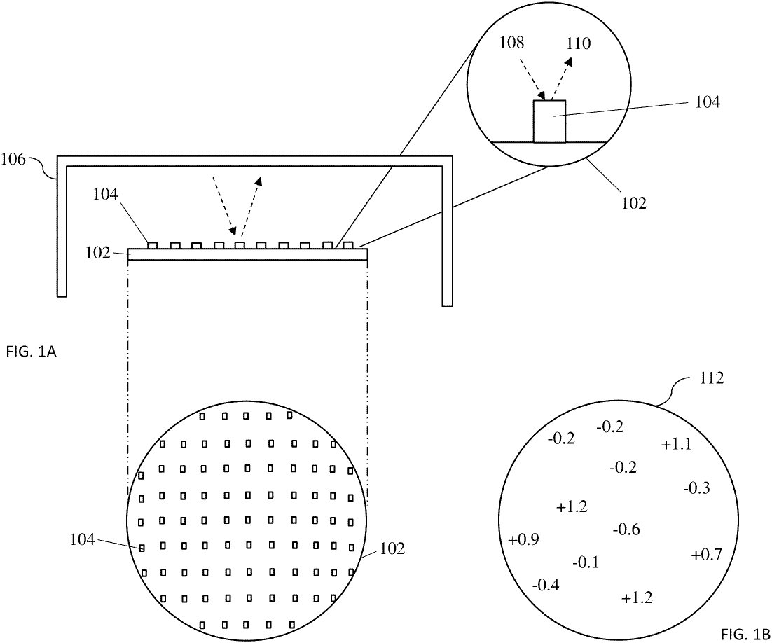

Turning now to a more detailed description of fabrication operations and resulting structures according to aspects of the invention, FIG. 1A depicts a cross-sectional view and a top-down view of a semiconductor wafer (or substrate) 102 configured with one or more test structures 104 according to one or more embodiments of the invention. In some embodiments of the invention, the semiconductor wafer 102 is placed under or within an in-situ feedback tool 106 (as shown). The size, shape, and composition of the semiconductor wafer 102 is not meant to be particularly limited. In some embodiments of the invention, the semiconductor wafer 102 is a silicon wafer of approximately circular shape.

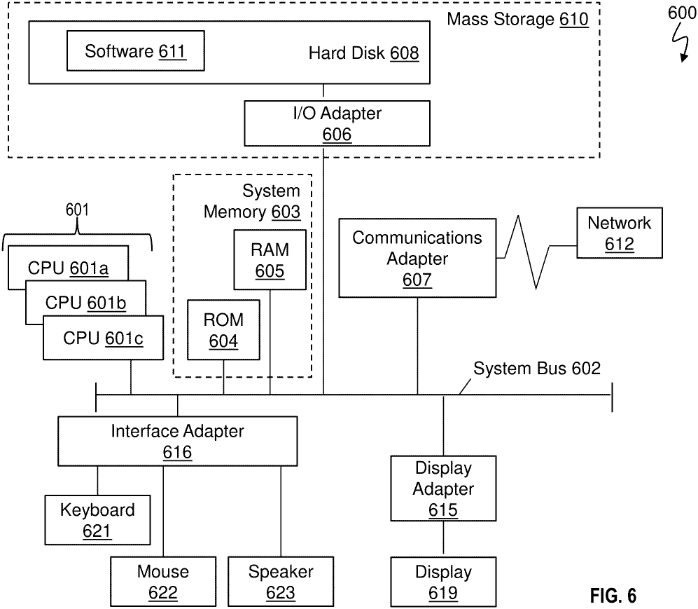

In accordance with aspects of the invention, the in-situ feedback tool 106 includes one or more sensors (not shown separately), a lithography module (not shown separately), and processor functionality (not shown separately). In some embodiments of the invention, the processor functionality of the in-situ feedback tool 106 can be implemented using the computer system 600 (shown in FIG. 6).

In some embodiments of the invention, the processor functionality is configured to direct the one or more sensors (or sensor assemblies) of the in-situ feedback tool 106 to record and/or measure a characteristic or property (also referred to as a compensation property) of the test structures 104. In some embodiments of the invention, the in-situ feedback tool 106 is configured to direct electromagnetic radiation 108 (e.g., visible light, X-rays, etc.) at the surface of the test structures 104 and to measure a quality (e.g., intensity, return time, etc.) of radiation 110 returning from the surface of the test structures 104. In this manner, the in-situ feedback tool 106 can measure a height, size, shape, or reflectivity of the one or more test structures 104. In some embodiments of the invention, the in-situ feedback tool 106 is configured to accommodate a range of possible sizes and shapes of the semiconductor wafer 102.

In some embodiments of the invention, the processor functionality is configured to determine a local condition of the semiconductor wafer 102 for each measured property of the plurality of test structures 104. For example, a difference in measured heights of two adjacent test structures can indicate a degree of wafer warpage or a degree of topography of a surface of the semiconductor wafer 102.

In some embodiments of the invention, the processor functionality is configured determine a localized process-based compensation for each local condition. The precise type of the localized process-based compensation is not meant to be particularly limited, but can include, for example, one or more of a focus adjustment of the lithography module (e.g., an increase or decrease in focus depth over the respective region of the semiconductor wafer 102), a resist volume adjustment of the lithography module (e.g., an increase or decrease in the amount of resist dispensed over the respective region of the semiconductor wafer 102), and an exposure setting adjustment of the lithography module (e.g., an increase or decrease in the expose timing for the respective region of the semiconductor wafer 102).

In some embodiments of the invention, the processor functionality is configured to direct the lithography module to provide, for each local condition, the respective localized process-based compensation on the surface of the semiconductor wafer. For example, the processor functionality can direct the lithography module to adjust the focus, resist volume, or exposure settings at each particular region of the semiconductor wafer 102.

As shown, the test structures 104 can be distributed throughout the surface of the semiconductor wafer 102. In some embodiments of the invention, the test structures 104 are uniformly spaced across the surface of the semiconductor wafer 102. However, while the semiconductor wafer 102 is depicted as having a particular arrangement of test structures 104 for ease of illustration and discussion, it is understood that any desired pattern, placement, or number of test structures can be formed on the semiconductor wafer 102. For example, the test structures 104 need not be uniformly distributed across the semiconductor wafer 102.

In some embodiments of the invention, one or more regions of the semiconductor wafer 102 contain a higher (or lower) concentration of test structures 104. This type of configuration can be useful when wafer/chip level variations are known to be more (or less) severe in particular regions of the semiconductor wafer 102. For example, the density of test structures 104 can be greater (or less) in edge regions of the semiconductor wafer 102 (within, e.g., 5 percent to 25 percent of the radius of the semiconductor wafer 102). Similarly, the density of test structures 104 can be greater (or less) in arbitrary internal regions of the semiconductor wafer 102 (corresponding, e.g., to known component locations susceptible to wafer/chip variations).

In some embodiments of the invention, the general shape and size of the test structures 104 can be consistent/uniform across the semiconductor wafer 102 (as shown). In some embodiments of the invention, the shape and/or size of the test structures 104 can vary as desired. For example, test structures 104 along an edge of the semiconductor wafer 102 can be formed to a first size, while test structures 104 in the interior portions of the semiconductor wafer 102 can be formed to a second, different size (larger or smaller). The pitch (edge-to-edge spacing) between test structures 104 can be similarly varied as desired.

As discussed previously, the in-situ feedback tool 106 can include one or more sensors configured to record and/or measure a compensation property of the semiconductor wafer 102. In some embodiments of the invention, the compensation property is measured at different regions of the semiconductor wafer 102 using the test structures 104. In some embodiments of the invention, the in-situ feedback tool 106 uses the sensors and local or remote processor functionality (e.g., computer system 600 shown in FIG. 6) to record the compensation property at each measured region. The recorded compensation property at each measured region is used by the processor functionality to build a compensation mapping (or readout) across the surface of the semiconductor wafer 102.

An example compensation mapping 112 is shown in FIG. 1B. The compensation mapping 112 can include an arbitrary number of compensation property values. In some embodiments of the invention, the compensation mapping 112 includes a compensation property value for each of the test structures 104. In some embodiments of the invention, a single compensation property value is determined for two or more test structures 104 collectively. For example, the value of a single collective compensation property for three adjacent test structures can be the average value over the respective region covered by the three test structures. In this manner, localized in-situ compensation can be provided at any level of granularity.

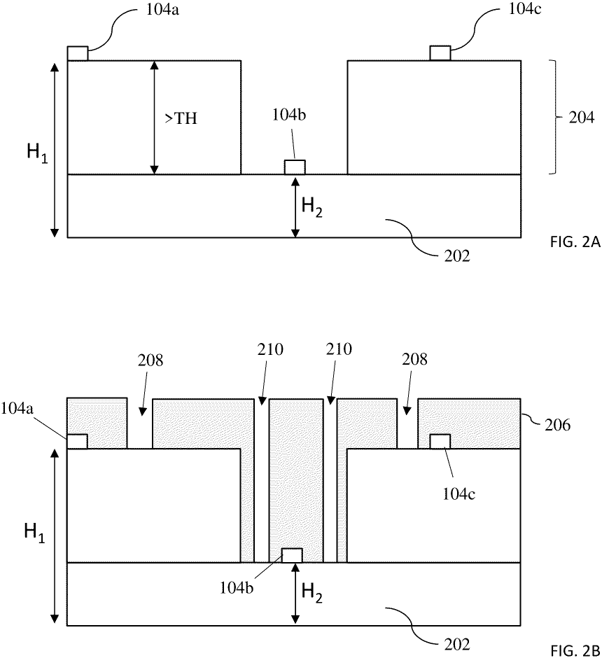

FIG. 2A depicts a cross-sectional view of a semiconductor wafer 202 configured with one or more test structures 104 (104a, 104b, 104c, etc.) according to one or more embodiments of the invention. In some embodiments of the invention, the semiconductor wafer 202 includes one or more regions 204 of varying topography. In some embodiments of the invention, an in-situ feedback tool (e.g., the in-situ feedback tool 106 discussed with respect to FIG. 1A) measures and compensates for these topography variations.

In some embodiments of the invention, the in-situ feedback tool is a lithography scanner (not separately shown). In some embodiments of the invention, the lithography scanner scans the test structures 104 to determine the relative heights of each of the test structures 104. The variation of heights across the semiconductor wafer 202 can be used to infer changes in topography. For example, one test element 104a can be at a first height (H1) and another test element 104b can be at a second height (H2) that is different than H1 (e.g., H2 > or < H1).

In some embodiments of the invention, changes in topography can be compensated for during lithography (patterning). For example, the lithography scanner can provide localized process-based compensation during lithography by varying focal distance depending on the topography assessment (i.e., the difference in heights H1 and H2 for test elements 104a, 104b). Other compensation schemes which do not rely on focal distances are possible. For example, compensation may also include changes to resist dispensing volume and changes to exposure settings to adjust for identified topography variations.

These types of topography feedback (compensation) mechanisms can used to provide localized process-based compensation for different parts of the semiconductor wafer 202. Advantageously, these compensation schemes can be used to check the after-clamp topography of the wafer and can compensate for topography variations (a) within die, (b) within wafer, and (c) within particular section(s) of wafer.

In some embodiments of the invention, lithography compensations are only made for topography changes that exceed a predetermined threshold (“>TH”). For example, a compensation threshold can be set to 5 microns (any value is possible). In this scenario a compensation (change to focal distance, resist volume, exposure setting, etc.) is only made when the height between two test elements exceeds this threshold. As shown in FIG. 2A, the test elements 104a and 104b are separated by a distance that exceeds TH. Consequently, a topography compensation will be made during lithography. FIG. 2B illustrates an example topography compensation.

As shown in FIG. 2B, a patterned resist 206 is formed over the semiconductor wafer 202. The actual structure of the patterned resist 206 is not meant to be particularly limited and is provided for ease of discussion only. As further shown in FIG. 2B, the topography compensation (e.g., change in focus depth) has resulted in relatively wide resist gaps 208 adjacent to the test elements 104a, 104c, while relatively narrow resist gaps 210 are formed adjacent to test element 104b. The actual difference in resist gap spacing (or resist volume, etc.) shown in FIG. 2B is provided only to illustrate the technique.

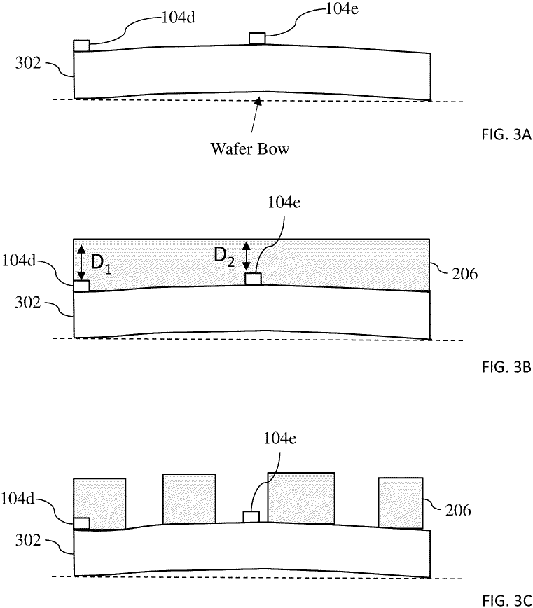

FIG. 3A depicts a cross-sectional view of a semiconductor wafer 302 configured with one or more test structures 104 according to one or more embodiments of the invention. In some embodiments of the invention, the semiconductor wafer 302 is a bowed wafer (as shown). The degree of bowing is not meant to be particularly limited and an example degree of wafer bow is shown for ease of discussion only. In some embodiments of the invention, an in-situ feedback tool (e.g., the in-situ feedback tool 106 discussed with respect to FIG. 1A) measures and compensates for wafer bow.

In some embodiments of the invention, the in-situ feedback tool is a lithography scanner (not separately shown). As shown in FIG. 3B, the lithography scanner scans the depth of the test structures 104 to measure the degree of wafer bow at a variety of locations on the semiconductor wafer 302. In some embodiments of the invention, the depth of a test structure is measured as the distance from the topmost surface of the respective test structure to the top of the patterned resist 206 (or other reference layer or structure). The variation of depths across the semiconductor wafer 302 can be used to build a mapping of wafer bow (not separately shown). For example, a first depth (D₁) for a first test element 104d can be greater than a second depth (D₂) for a second test element 104e. Consequently, a higher degree of wafer bow can be attributed to the region of the semiconductor wafer 302 adjacent to the second test element 104e.

In some embodiments of the invention, changes in wafer bow can be compensated for during lithography (patterning). FIG. 3C illustrates an example wafer bow compensation. In some embodiments of the invention, the lithography scanner can provide localized process-based compensation during lithography by varying focal distance depending on the wafer bow assessment (i.e., the difference in depths D1 and D2 for test elements 104d, 104e). Other compensation schemes which do not rely on focal distances are possible. For example, compensation may also include changes to resist dispensing volume and changes to exposure settings to adjust for identified topography variations.

These types of wafer bow feedback (compensation) mechanisms can used to provide localized process-based compensation for different parts of the semiconductor wafer 302. Advantageously, these compensation schemes can be used to check after-clamp wafer bow and can compensate for wafer bow variations (a) within die, (b) within wafer, and (c) within particular section(s) of wafer.

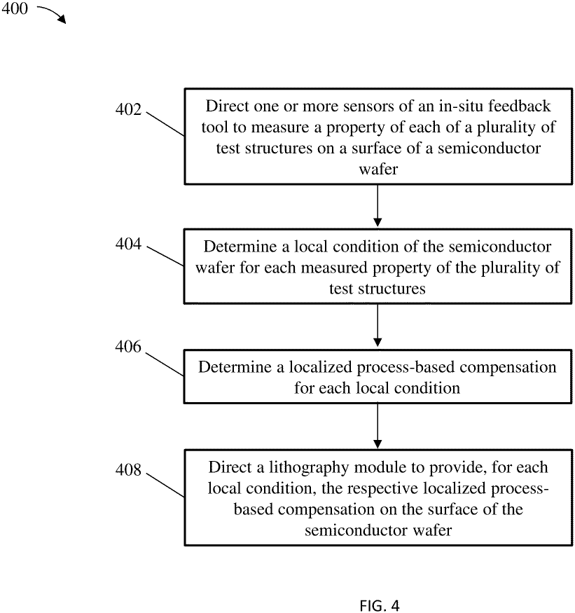

FIG. 4 depicts a flow diagram illustrating a method 400 of using a processor to control an in-situ feedback tool to perform process-based compensation according to one or more embodiments of the invention. As shown at block 402, the processor directs one or more sensors of the in-situ feedback tool to measure a property of each of a plurality of test structures on a surface of a semiconductor wafer. In some embodiments of the invention, the property of each respective test structure comprises a height, a size, a shape, or a reflectivity of the test structure.

At block 404, the processor determines a local condition of the semiconductor wafer for each measured property of the plurality of test structures. In some embodiments of the invention, the local condition comprises a topography variation or a degree of wafer bow of the semiconductor wafer.

At block 406, the processor determines a localized process-based compensation for each local condition. In some embodiments of the invention, the localized process-based compensation comprises one or more of a lithography focus adjustment of a lithography module, a resist volume adjustment of the lithography module, and an exposure setting adjustment of the lithography module.

At block 408, the processor directs the lithography module to provide, for each local condition, the respective localized process-based compensation on the surface of the semiconductor wafer. In some embodiments of the invention, the lithography module is incorporated within the in-situ feedback tool. In other embodiments, the lithography module is a separate device from the in-situ feedback tool.

In some embodiments of the invention, the test structures are uniformly spaced across the surface of the semiconductor wafer. In some embodiments of the invention, a density of test structures is greater in a first region of the semiconductor wafer than in a second region of the semiconductor wafer. In some embodiments of the invention, the density of test structures is greater along a perimeter of the semiconductor wafer than in a center region of the semiconductor wafer. In some embodiments of the invention, the density of test structures is lower along a perimeter of the semiconductor wafer than in a center region of the semiconductor wafer. In some embodiments of the invention, a size of the test structures varies across the surface of the semiconductor wafer. In some embodiments of the invention, an edge-to-edge pitch between test structures varies across the surface of the semiconductor wafer.

The method 400 can further include building, by the processor, a compensation mapping based on the measured properties of each of the plurality of test structures. In some embodiments of the invention, the compensation mapping encodes the measured properties of the test structures.

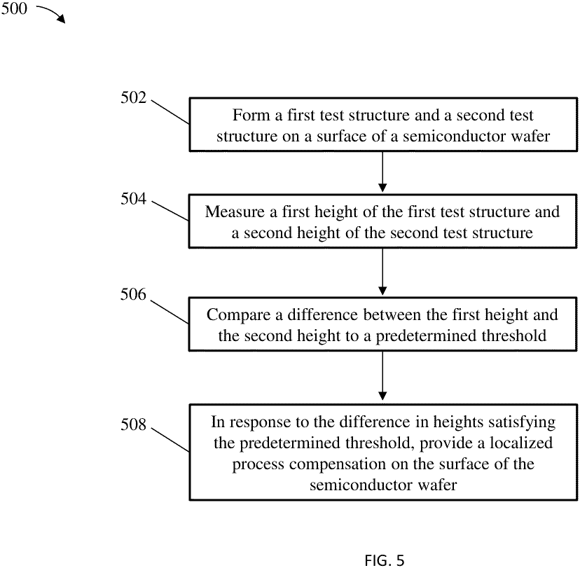

FIG. 5 depicts a flow diagram illustrating an in-situ wafer feedback method 500 for localized process-based compensation according to one or more embodiments of the invention. As shown at block 502, a first test structure and a second test structure are formed on a surface of a semiconductor wafer.

At block 504, an in-situ feedback tool measures a first height of the first test structure and a second height of the second test structure. At block 506, a difference between the first height and the second height is compared to a predetermined threshold. In some embodiments of the invention, the predetermined threshold comprises a difference in height of at least 5 microns.

At block 508, in response to the difference in heights satisfying the predetermined threshold, a localized process-based compensation is provided on the surface of the semiconductor wafer. In some embodiments of the invention, the localized process-based compensation comprises one or more of a lithography focus adjustment, a resist volume adjustment, and an exposure setting adjustment.

The method 500 can further include determining a change in topography of the semiconductor wafer based on the measured first height and the measured second height. In some embodiments of the invention, a degree of wafer bow of the semiconductor wafer is determined based on the measured first height and the measured second height.

Turning now to FIG. 6, a computer system 600 is generally shown in accordance with one or more embodiments of the invention. The computer system 600 can be an electronic, computer framework comprising and/or employing any number and combination of computing devices and networks utilizing various communication technologies, as described herein. The computer system 600 can be scalable, extensible, and modular, with the ability to change to different services or reconfigure some features independently of others. The computer system 600 may be, for example, a server, desktop computer, laptop computer, tablet computer, or smartphone. Computer system 600 may be described in the general context of computer system executable instructions, such as program modules, being executed by a computer system. Generally, program modules may include routines, programs, objects, components, logic, data structures, and so on that perform particular tasks or implement particular abstract data types. Computer system 600 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 6, the computer system 600 has one or more central processing units (CPU(s)) 601a, 601b, 601c, etc., (collectively or generically referred to as processor(s) 601). The processors 601 can be a single-core processor, multi-core processor, computing cluster, or any number of other configurations. The processors 601, also referred to as processing circuits, are coupled via a system bus 602 to a system memory 603 and various other components. The system memory 603 can include a read only memory (ROM) 604 and a random access memory (RAM) 605. The ROM 604 is coupled to the system bus 602 and may include a basic input/output system (BIOS) or its successors like Unified Extensible Firmware Interface (UEFI), which controls certain basic functions of the computer system 600. The RAM is read-write memory coupled to the system bus 602 for use by the processors 601. The system memory 603 provides temporary memory space for operations of said instructions during operation. The system memory 603 can include random access memory (RAM), read only memory, flash memory, or any other suitable memory systems.

The computer system 600 comprises an input/output (I/O) adapter 606 and a communications adapter 607 coupled to the system bus 602. The I/O adapter 606 may be a small computer system interface (SCSI) adapter that communicates with a hard disk 608 and/or any other similar component. The I/O adapter 606 and the hard disk 608 are collectively referred to herein as a mass storage 610.

Software 611 for execution on the computer system 600 may be stored in the mass storage 610. The mass storage 610 is an example of a tangible storage medium readable by the processors 601, where the software 611 is stored as instructions for execution by the processors 601 to cause the computer system 600 to operate, such as is described herein below with respect to the various Figures. Examples of computer program product and the execution of such instruction is discussed herein in more detail. The communications adapter 607 interconnects the system bus 602 with a network 612, which may be an outside network, enabling the computer system 600 to communicate with other such systems. In one embodiment, a portion of the system memory 603 and the mass storage 610 collectively store an operating system, which may be any appropriate operating system to coordinate the functions of the various components shown in FIG. 6.

Additional input/output devices are shown as connected to the system bus 602 via a display adapter 615 and an interface adapter 616. In one embodiment, the adapters 606, 607, 615, and 616 may be connected to one or more I/O buses that are connected to the system bus 602 via an intermediate bus bridge (not shown). A display 619 (e.g., a screen or a display monitor) is connected to the system bus 602 by the display adapter 615, which may include a graphics controller to improve the performance of graphics intensive applications and a video controller. A keyboard 621, a mouse 622, a speaker 623, etc., can be interconnected to the system bus 602 via the interface adapter 616, which may include, for example, a Super I/O chip integrating multiple device adapters into a single integrated circuit. Suitable I/O buses for connecting peripheral devices such as hard disk controllers, network adapters, and graphics adapters typically include common protocols, such as the Peripheral Component Interconnect (PCI) and the Peripheral Component Interconnect Express (PCIe). Thus, as configured in FIG. 6, the computer system 600 includes processing capability in the form of the processors 601, and, storage capability including the system memory 603 and the mass storage 610, input means such as the keyboard 621 and the mouse 622, and output capability including the speaker 623 and the display 619.

In some embodiments, the communications adapter 607 can transmit data using any suitable interface or protocol, such as the internet small computer system interface, among others. The network 612 may be a cellular network, a radio network, a wide area network (WAN), a local area network (LAN), or the Internet, among others. An external computing device may connect to the computer system 600 through the network 612. In some examples, an external computing device may be an external webserver or a cloud computing node.

It is to be understood that the block diagram of FIG. 6 is not intended to indicate that the computer system 600 is to include all of the components shown in FIG. 6. Rather, the computer system 600 can include any appropriate fewer or additional components not illustrated in FIG. 6 (e.g., additional memory components, embedded controllers, modules, additional network interfaces, etc.). Further, the embodiments described herein with respect to computer system 600 may be implemented with any appropriate logic, wherein the logic, as referred to herein, can include any suitable hardware (e.g., a processor, an embedded controller, or an application specific integrated circuit, among others), software (e.g., an application, among others), firmware, or any suitable combination of hardware, software, and firmware, in various embodiments.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

The phrase “selective to,” such as, for example, “a first element selective to a second element,” means that the first element can be etched and the second element can act as an etch stop.

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The present invention may be a system, a method, and/or a computer program product at any possible technical detail level of integration. The computer program product may include a computer readable storage medium (or media) having computer readable program instructions thereon for causing a processor to carry out aspects of the present invention.

For example, any or all of the blocks depicted with respect to FIGS. 4 and 5 can be implemented as part of a computer-implemented method, a system, or as a computer program product. The system can include a memory having computer readable instructions and one or more processors for executing the computer readable instructions, the computer readable instructions controlling the one or more processors to perform operations including those depicted with respect to FIGS. 4 and 5. The computer program product can include a computer readable storage medium having program instructions embodied therewith, the program instructions executable by one or more processors to cause the one or more processors to perform operations including those depicted with respect to FIGS. 4 and 5.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of using a processor to control an in-situ feedback tool to perform process-based compensation, the method comprising:
directing one or more sensors of the in-situ feedback tool to measure a property of each of a plurality of test structures on a surface of a semiconductor wafer;
determining, by the processor, a local condition of the semiconductor wafer for each measured property of the plurality of test structures;
determining, by the processor, a localized process-based compensation for each local condition; and
directing a lithography module to provide, for each local condition, the respective localized process-based compensation on the surface of the semiconductor wafer.

2. The method of claim 1, wherein the property of each respective test structure comprises a height, a size, a shape, or a reflectivity of the test structure.

3. The method of claim 2, wherein the local condition comprises a topography variation or a degree of wafer bow of the semiconductor wafer.

4. The method of claim 3, wherein the localized process-based compensation comprises one or more of a focus adjustment of the lithography module, a resist volume adjustment of the lithography module, and an exposure setting adjustment of the lithography module.

5. The method of claim 1 further comprising building, by the processor, a compensation mapping based on the measured properties of each of the plurality of test structures.

6. The method of claim 1, wherein the test structures are uniformly spaced across the surface of the semiconductor wafer.

7. The method of claim 1, wherein a density of test structures is greater in a first region of the semiconductor wafer than in a second region of the semiconductor wafer.

8. The method of claim 7, wherein the density of test structures is greater along a perimeter of the semiconductor wafer than in a center region of the semiconductor wafer.

9. The method of claim 7, wherein the density of test structures is lower along a perimeter of the semiconductor wafer than in a center region of the semiconductor wafer.

10. The method of claim 1, wherein a size of the test structures varies across the surface of the semiconductor wafer.

11. The method of claim 1, wherein an edge-to-edge pitch between test structures varies across the surface of the semiconductor wafer.

12. A method for forming a semiconductor device, the method comprising:
forming a first test structure and a second test structure on a surface of a semiconductor wafer;
measuring, by an in-situ feedback tool, a first height of the first test structure and a second height of the second test structure;
comparing a difference between the first height and the second height to a predetermined threshold; and
in response to the difference in heights satisfying the predetermined threshold, providing a localized process-based compensation on the surface of the semiconductor wafer.

13. The method of claim 12 further comprising determining a change in topography of the semiconductor wafer based on the measured first height and the measured second height.

14. The method of claim 12 further comprising determining a degree of wafer bow of the semiconductor wafer based on the measured first height and the measured second height.

15. The method of claim 12, wherein the predetermined threshold comprises a difference in height of at least 5 microns.

16. The method of claim 12, wherein the localized process-based compensation comprises one or more of a lithography focus adjustment, a resist volume adjustment, and an exposure setting adjustment.

17. A semiconductor fabrication system for in-situ process-based compensation, the system comprising:
an in-situ feedback tool comprising one or more sensors;
a lithography module; and
a processor, the processor configured to:
direct the one or more sensors of the in-situ feedback tool to measure a property of each of a plurality of test structures on a surface of a semiconductor wafer;
determine a local condition of the semiconductor wafer for each measured property of the plurality of test structures;
determine a localized process-based compensation for each local condition; and
direct the lithography module to provide, for each local condition, the respective localized process-based compensation on the surface of the semiconductor wafer.

18. The system of claim 17, wherein the property of each respective test structure comprises a height, a size, a shape, or a reflectivity of the test structure.

19. The system of claim 17, wherein the local condition comprises a topography variation or a degree of wafer bow of the semiconductor wafer.

20. The system of claim 17, wherein the localized process-based compensation comprises one or more of a focus adjustment of the lithography module, a resist volume adjustment of the lithography module, and an exposure setting adjustment of the lithography module.
